(19) United States
(12) Patent Application Publication
(10) Pub. No.: US 2002/0118032 A1
(43) Pub. Date: Aug. 29, 2002

(54) Heating apparatus containing an array of surface mount components for DUT performance testing

(75) Inventors: Joe Norris, Dublin, OH (US); Ken Hackworth, Galena, OH (US)

Correspondence Address: George C. Beck, FOLEY & LARDNER, Washington Harbour, 3000 K Street, N.W., Suite 500, Washington, DC, 20007-5109, US

(73) Assignee: Schlumberger Technologies, Inc.

(21) Appl. No.: 09/794,915

(22) Filed: Feb. 28, 2001

(51) Int. Cl. G01R 31/02

(52) U.S. Cl. 324/760

(57) ABSTRACT

A heating apparatus for heating a DUT is provided. The apparatus contains at least one DUT contact area adapted to be in contact with a single DUT and a plurality of discrete heating elements, such as surface mount resistors, in thermal communication with the DUT contact area. The apparatus also contains an enclosure enclosing the heating elements and a heat exchange fluid passage bounded by an outer surface of the heating elements and an inner surface of the enclosure.

### BACKGROUND OF THE INVENTION

1. Field of the Invention

This invention relates generally to a heating apparatus and specifically to a heating apparatus containing an array of surface mount resistors and a heat exchange fluid path used for DUT performance testing.

2. Description of the Related Art

When semiconductor devices are being tested, for example to determine their operating frequency, it is desired to evaluate their performance at a variety of temperatures, ranging from cold to hot. Prior art temperature control systems contain an electric heater whose front surface makes contact with the device under test (“DUT”) where back surface is coupled to a heat sink. The heat sink is often a heat exchange fluid pipe (i.e., a cooling fluid pipe). An example of such a temperature control system is illustrated, for example in U.S. Pat. No. 5,821,505, (the '505 patent) incorporated herein by reference in its entirety, where a single metal thin film resistive heater is provided on an aluminum nitride (AlN) substrate.

While the temperature control system described in the '505 patent provides a good temperature control for DUT testing, such a system is difficult to manufacture and calibrate, and its design is inflexible in terms of physical size, heater resistance and temperature detector properties. Furthermore, this system requires specialized high voltage control equipment, a customized temperature detector and a customized temperature correlation database. These features increase the cost and complexity of the system.

Another drawback of the prior art systems is that a separate heat exchange fluid pipe is attached to the heater via a thermally conductive epoxy. However, the epoxy often contains voids, which reduces the thermal conductivity between the heater and the pipe. The heat exchange fluid pipe, which is often made of copper, sometimes warps during brazing and thus leaks. Furthermore, the prior art temperature control system provides non-uniform heating due to the cold spots adjacent to the heat exchange fluid inlet.

### SUMMARY OF THE INVENTION

According to one preferred aspect of the present invention, there is provided a heating apparatus, comprising at least one DUT contact area adapted to be in contact with a single DUT, a plurality of discrete heating elements in thermal communication with the DUT contact area, and a heat exchange fluid passage.

According to another preferred aspect of the present invention, there is provided a heating apparatus, comprising a plurality of discrete heating elements, an enclosure enclosing the heating elements, and a heat exchange fluid passage bounded by an outer surface of the heating elements and an inner surface of the enclosure.

According to another preferred aspect of the present invention, there is provided a heating apparatus, comprising at least one DUT contact area adapted to be in contact with a single DUT, a plurality of discrete heating elements in thermal communication with the DUT contact area, an enclosure enclosing the heating elements, and a heat exchange fluid passage bounded by an outer surface of the heating elements and an inner surface of the enclosure.

According to another preferred aspect of the present invention, there is provided a heating apparatus, comprising at least one DUT contact area adapted to be in contact with a single DUT, a first set of discrete heating elements in thermal communication with a first portion of the DUT contact area, a second set of discrete heating elements in thermal communication with a second portion of the DUT contact area adapted to heat the second portion of the DUT contact area to a lower temperature than the first portion of the DUT contact area, and a heat exchange fluid passage.

According to another preferred aspect of the present invention, there is provided a method of making a heating apparatus, comprising providing a DUT contact surface, mounting a plurality of discrete surface mount resistors on a portion of the DUT contact surface adapted to be in contact with a single DUT, and placing an enclosure over the resistors to form a heat exchange fluid passage bounded by an outer surface of the resistors and an inner surface of the enclosure.

According to another preferred aspect of the present invention, there is provided a method of testing a DUT, comprising placing the DUT in contact with a DUT contact surface, providing an electrical testing input signal to the DUT, receiving an electrical testing output signal from the DUT, heating the DUT with a plurality of discrete heating elements located in thermal communication with the DUT contact surface, and providing a heat exchange fluid into a heat exchange passage adjacent to the plurality of discrete heating elements.

### BRIEF DESCRIPTION OF THE DRAWINGS

FIG. 1 illustrates a side cross sectional view of a heating apparatus according to a first preferred embodiment of the present invention.

FIG. 2A illustrates a top view of a heating apparatus according to the first preferred embodiment of the present invention.

FIG. 2B illustrates a side cross sectional view of a heating apparatus along line A-A′ in FIG. 2A.

FIG. 3 illustrates a top view of a heating apparatus according to a second preferred embodiment of the present invention.

FIG. 4 illustrates a schematic side cross sectional view of a DUT testing system according to one preferred embodiment of the present invention.

FIG. 5 illustrates a schematic side cross sectional view of a DUT testing system according to another preferred embodiment of the present invention.

### DETAILED DESCRIPTION OF THE PREFERRED EMBODIMENTS

The present inventors have determined that a design of a heating apparatus may be rendered flexible if a plurality of discrete heating elements are placed in thermal communication with the DUT contact area. The use of expensive custom-made equipment can be avoided and the apparatus manufacturing can be simplified if commercially available surface mount resistors are used as the heating elements and a commercially available resistance temperature detector(s) (“RTD”) is used to measure the DUT temperature. Furthermore, the problems with the separate prior art heat exchange fluid pipe may be avoided by eliminating this pipe. Instead, the heat exchange fluid preferably flows directly over the outer surfaces of the resistors in a heat exchange fluid passage bounded by the outer resistor surfaces and the inner surface of the heating apparatus enclosure.

If desired, the cold spot(s) adjacent to the heat exchange fluid inlet may be reduced or eliminated by placing a higher density of resistors in a first apparatus area adjacent to the inlet than in a second area distal from the inlet. Furthermore, a higher density of resistors may be placed in a first apparatus portion near to a known DUT cold area or a lower density of resistors may be placed near a known DUT hot area. Alternatively, a first set of resistors with a first resistance value may be placed in the first heating apparatus portion near a known DUT cold area or the cold spot adjacent to the heat exchange fluid inlet. A second set of resistors with a second resistance value different than the first resistance value may be placed in a second apparatus portion near a known DUT hot area or the area distal from the inlet. The first and second sets of resistors may have the same or different resistor density.

FIG. 1 illustrates a heating apparatus 1 according to the first preferred embodiment of the present invention. The heating apparatus contains a plurality of discrete heating elements. Preferably, the heating elements comprise surface mount resistors 3. The resistors 3 preferably comprise any commercially available, off the shelf surface mount resistors, in contrast to the metal thin film resistors of the '505 patent. For example, the resistors may be 0.200″×0.100″ (standard 2010 component size) or 0.040″×0.020″ (standard 0402 component size) high power resistors. However, while surface mount resistors are preferred as the discrete heating elements, other heating devices, such as thin film resistors and thermoelectric devices (i.e., Peltier devices) may be used instead.

The resistors 3 are preferably mounted over an inner surface of a pad or substrate 5. For example, the pad 5 can comprise any ceramic material, such as AlN, or other materials, such as high temperature plastics. The pad 5 can be made of a compliant material, such as a high temperature plastic, which conforms to the surface of the DUT. The compliance reduces the thermal resistance from the heater to the DUT. If a material of the pad 5 has poor thermal conductive properties, then the thickness of the pad 5 can be minimized to reduce thermal resistance. The outer surface of the pad 5 comprises a DUT contact area 7 which is adapted to be in contact with one or more DUTs. For example, in a preferred aspect of the present invention, the DUT contact area 7 has a size which is sufficient to fit a single DUT. However, the pad 5 may be omitted if desired, and the DUT contact area 7 would comprise the lower surface of the resistors 3. Thus, the resistors 3 would directly contact the DUT. While FIG. 1 illustrates a heating apparatus with a single DUT contact area 7, the apparatus 1 may contain a plurality of DUT contact areas 7, where each DUT contact area 7 is adapted to be in contact with a single DUT and where each DUT contact area is in thermal communication with a plurality of resistors 3.

FIG. 2A illustrates a top view of the heating apparatus 1 according to the first preferred embodiment. FIG. 2B is a side cross sectional view along line A-A′ in FIG. 2A. In this embodiment, the apparatus 1 contains twelve resistors 3 arranged in a zigzag pattern. However, the apparatus 1 may contain two or more resistors 3 arranged in any desired pattern. The length and width of the apparatus 1 is selected to fit a DUT in contact with the contact area 7 (illustrated by the dashed lines). For example, the apparatus 1 may have a pad size of 4″ by 4″.

The apparatus 1 also contains at least one temperature sensor, as illustrated in FIG. 2A. Preferably, the temperature sensor is a surface mount RTD 9, such as a commercially available RTD precalibrated to industry standards. Alternatively, the sensor may comprise a thermocouple, thermal diode, a temperature sensor unit with built in signal conditioning or signal processing capabilities, or other temperature measurement device. While only one RTD 9 is illustrated in FIG. 2A, the apparatus 1 may contain two or more RTDs 9 located in different portions over area 7 to obtain an average temperature across the DUT or the temperature in multiple specific zones of the DUT in contact with area 7.

The pad 5 contains metal conductors or traces 11 along its inner surface. The resistors 3 and the RTD(s) 9 are surface mounted onto the conductors 11, as illustrated in FIG. 2A. Preferably, the conductors comprise copper and are laid out in a manner similar to the conductors on a printed circuit board.

As illustrated in FIG. 1, the resistors 3 are preferably soldered to the conductors 11 by solder 13. Furthermore, an optional thermally conductive material, such as a thermal epoxy 15, is placed between the bottom surface of the resistors 3 and the inner surface of the pad 5, to enhance the thermal conductivity between the resistors 3 and the pad 5.

The conductors 11 are preferably connected to external electronic components by one or more post connectors 17, as illustrated in FIGS. 1 and 2. The post connector 17 is a conductive rod, such as a metal rod, whose bottom portion contacts the metal conductors 11, and whose top portion protrudes through the epoxy sealed opening 18 in the enclosure 19 of the apparatus 1. The top portion of the post connector 17 that is exposed above the enclosure 19 is connected to external electronic components via an electrical wire or other electrically conductive element, as will be described in more detail below. The post connectors 17 may be spring loaded “pogo pins” that make electrical contact with the conductors 11 by a mechanical connection or a solder connection. Preferably the post connectors 17 are soldered to the conductors 11 using a solder with good thermal and expansive properties. The resistors 3 may be connected in parallel, in series or in another arrangement as desired.

The enclosure 19 overlies the pad 5 and the resistors 3. The enclosure 19 may be made of any suitable material, such as plastic, metal or ceramic. If desired, the material of the enclosure may be the same as the material of the pad 5. Preferably, the enclosure 19 is attached to the pad 5 via adhesive epoxy 21, as illustrated in FIG. 1. If desired, the enclosure 19 may be alternatively soldered or brazed to the pad 5. Furthermore, the connection between the enclosure 19 and the pad 5 may be reinforced by a fastener or mechanical reinforcement feature, such as a groove. The bottom surface of the pad 5 is preferably flush with the bottom surface of the enclosure 19 as shown in FIG. 1. Of course, the enclosure 19 may be configured to only contact the top and/or side surfaces of the pad 5, if desired.

The space between the inner surface of the enclosure 19 and the outer surface of the resistors 3 comprises a heat exchange fluid passage 23. Specifically, a first area between sidewalls of the resistors 3, the inner surface of the enclosure 19 and an inner surface of the pad 5 comprises the fluid passage 23. A heat exchange fluid inlet 25 is connected to the passage 23 to allow a heat exchange fluid (i.e., a cooling fluid) to flow directly from a fluid container outside the apparatus 1 over the top and/or side surfaces of the resistors 3. A heat exchange fluid outlet 27 is preferably located on the opposite side of apparatus 1, as illustrated in FIG. 2A. However, the fluid inlet 25 and outlet 27 may be located anywhere on the heating apparatus 1. For example, the fluid inlet 25 and outlet 27 passages may be located concentrically, with the inlet passage 25 located in the center surrounded by a larger, circular outlet passage 27.

A preferred heat exchange fluid contains ethyl nonafluorobutylether and ethyl nonafluoroisobutylether. Such a fluid is available under a trade name HFE7100 from 3M corporation. Preferably, HFE7100 is used at normal strength. HFE7100 is safe, nontoxic, non-explosive and non-conductive electrically. Alternatively, the heat exchange fluid may contain water with additives, such as methanol and/or ethylene glycol.

Preferably, a thermally insulating material 29, such as thermally insulating epoxy, is formed over the top surfaces of the resistors 3. The use of the thermally conductive epoxy 15 and the thermally insulating epoxy 29 increases the amount of heat extracted downwards toward the DUT contact area 7 from each resistor 3, and reduces the amount of heat extracted upwards toward the enclosure 19. The top of the resistors 3 does not have to be in contact with the enclosure 19. This would allow of passage of the heat exchange fluid between the enclosure 19 and the top of the resistors 3.

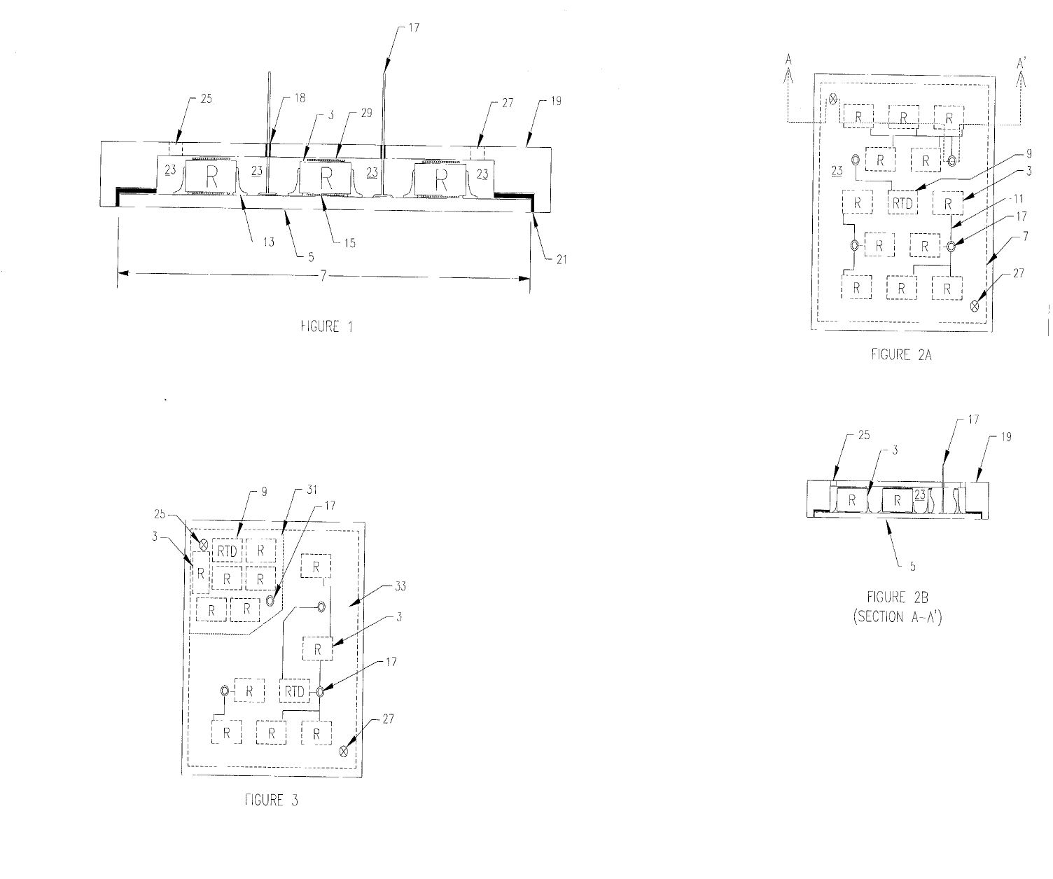

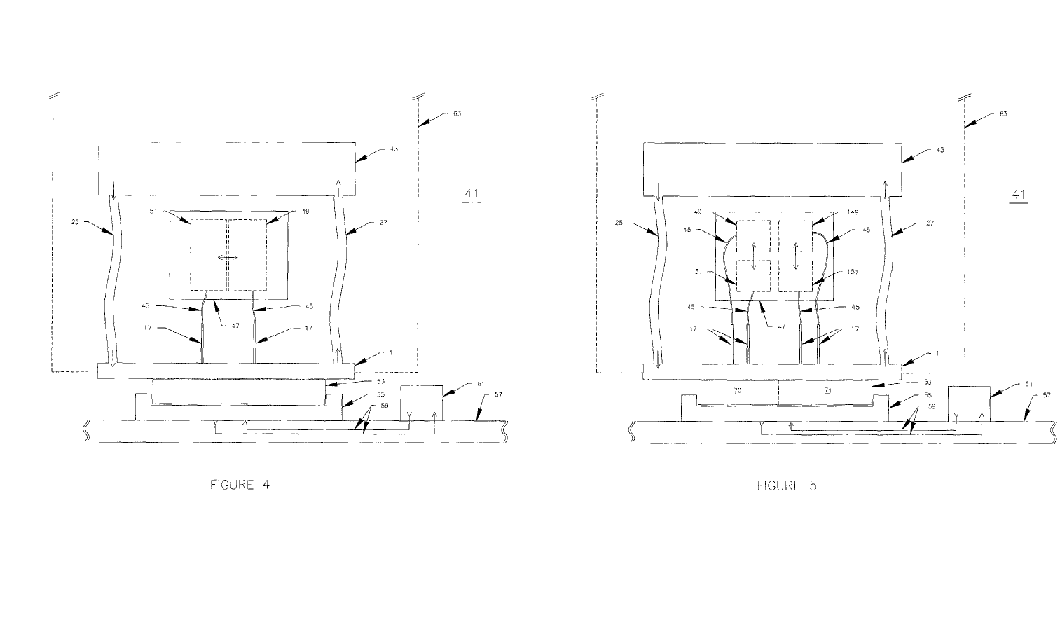

FIG. 3 illustrates a top view of a heating apparatus according to a second preferred embodiment of the present invention. In the apparatus of FIG. 3, a density of the first set of resistors 3 in a first area or portion 31 adjacent to the heat exchange fluid inlet 25 is higher than the density of the second set of resistors 3 in a second area or portion 33 distal from the heat exchange fluid inlet 25. In other words, there are more resistors per square millimeter adjacent to the inlet 25 than distal from the inlet 25. The higher resistor density provides a higher temperature adjacent the inlet 25, to counteract the cold spot that forms around the inlet 25 due to the cold heat exchange fluid entering through the inlet. Thus, the differential resistor density provides a more uniform temperature across the contact area 7 of the apparatus 1. If desired, the first area 31 and the second area 33 may contain separate RTDs 9. Furthermore, the particular resistor 3 arrangement illustrated in FIG. 3 is merely exemplary, and a differential resistor density may be achieved using other arrangements.

Furthermore, the resistance value of the first set of resistors 3 in a first area or portion 31 adjacent to the heat exchange fluid inlet 25 may be different than the resistance value of the second set of resistors 3 in a second area or portion 33 distal from the heat exchange fluid inlet 25. Thus, the resistors 3 in area 31 may have a higher density and/or a different resistance value than the resistors 3 in area 33, in order to counteract the effects of the fluid inlet. It should be noted that the resistance value of each resistor in a set may be the same as or different than the resistance value of other resistors in the set. Thus, it is preferred that an average resistance value of the resistors in one set be different than the average resistance value in another set. It is further noted that the resistance value of the first set of resistors in the first area 31 may be higher or lower than the resistance value of the second set of resistors in the second area 33 depending on the topology of the resistors (i.e., whether the resistors are connected in series, parallel or other arrangement) and on whether a constant current or a constant voltage is applied to the resistors. For example, if a constant and equal current is applied to the resistors connected in series, then the resistors in the first area 31 should have a higher resistance value than the resistors in the second area 33. In contrast, if a constant and equal voltage is applied to the resistors connected in parallel, then the resistors on the first area 31 should have a lower resistance value than the resistors in the second area 33.

In an alternative aspect of the second embodiment, the resistor density is determined by the location of hot spots in the DUT. During testing, first portions of the DUT, such as driver circuits, produce more heat than second portions of the DUT, such as memory circuits. Therefore, during testing, the first portions of the DUT are undesirably maintained at a higher temperature due to self heating than second portions of the same DUT. In order to maintain the entire DUT at about the same temperature, the first area(s) 31 of the heating apparatus 1 that are in the contact with the first DUT portions(s) are maintained at a somewhat higher temperature than second area(s) 33 of the heating apparatus 1 that are in the contact with the second DUT portion(s). This is accomplished by placing a higher density of resistors 3 in the first area 31 than in the second area 33. Furthermore, each area 31, 33 may contain a separate RTD 9, as described above.

Furthermore, the resistance value of the first set of resistors 3 in a first area or portion 31 may be different than the resistance value of the second set of resistors 3 in a second area or portion 33. Thus, the resistors 3 in area 31 may have a higher density and/or a different resistance value than the resistors 3 in area 33, in order to counteract the effects of the DUT hot and cold spots. Of course, there may be three or more sets of resistors 3, if the DUT contains three or more zones that have produce a different amount of heat during testing.

FIG. 4 schematically illustrates a DUT testing system 41 containing the heating apparatus 1. It should be noted that the arrangement shown in FIG. 4 is for schematic illustration purposes only, and the elements in FIG. 4 may be spatially arranged as desired. The testing system 41 contains the heating apparatus 1 illustrated in FIGS. 1, 2A, 2B and 3. The heating apparatus 1 contains a heat exchange fluid inlet 25 and outlet 27 which circulate the cooling fluid from the heat exchange fluid container 43 into the heat exchange fluid passage 23 within the heating apparatus 1. The post connectors 17 are connected to an electronic control module 47. For example, as shown in FIG. 4, the post connectors 17 may be connected to the control module 47 by conductors or wires 45 or by a standard, commercially available, pin and socket connector. Alternatively, the post connectors 17 may be spring loaded “pogo pins” which make a direct contact to a printed circuit board optionally containing the control module 47 on its surface, or which may be electrically connected to the control module 47. Furthermore, the posts connectors 17 may also be directly soldered to the printed circuit board or to the standard connector. The connector may be electrically connected to the control module 47 or the board may contain the control module 47. The electronic control module 47 contains at least a temperature controller 49 and a power source 51.

The temperature controller 49 may be a power regulator circuit, a computer and/or another type of processor. The temperature controller 49 receives an input signal from the RTD(s) 9 through one of the wires 45. Based on the input signal, the controller 49 determines the DUT temperature, using a conventional algorithm, such as the algorithm disclosed in U.S. Pat. No. 5,821,505, incorporated herein by reference in its entirety. For example, the controller 49 may determine the DUT temperature by comparing the RTD input signal to a predetermined set point DUT temperature signal. Based on these two signals and their rate of change, the controller 49 generates control signals to the power source 51, which indicate the amount of power which should be sent to the heating apparatus 1.

The power source 51 may be any type of an electrical power source, such as a variable power supply. The power source 51 receives the control signals from the controller 49 and a supply voltage from a voltage source, such as a power outlet. In response to the control signals, the power source sends a variable amount of power to the resistors 3 in the heating apparatus 1 through one or more second wires 45 and one or more second post connectors 17. In a preferred aspect of the present invention, the power source 51 is a low voltage variable power supply containing standard, off the shelf power amplifiers, preferably of 180 V or less. By using such amplifiers, the use of a high voltage power supply and custom amplifiers, as in the prior art systems, may be avoided.

In an alternative embodiment of the present invention, two or more power supplies 51, 151 are used, as illustrated in FIG. 5. Thus, a higher power signal (i.e., the current provided to the resistors) may be supplied from a first power supply 51 in electrical communication with a first set of heating elements, such as resistors 3, than a second power signal supplied from a second power supply 151 in electrical communication with a second set of heating elements. For example, the first set of resistors 3 may be located adjacent to a cold spot, such as the heat exchange fluid inlet 25 or a DUT cold spot, such as a memory area 70 of a DUT 53, while the second set of the resistors 3 may be located distal from the cold spot, such as adjacent to a driver area 71 of the DUT 53. Thus, the second set of resistors 3 is adapted to heat the adjacent section of the pad 5 to a lower temperature than the first set of resistors 3. There may be one temperature controller with plural temperature control channels to control the plural power supplies 51, 151 or there may be a first temperature controller 49 in electrical communication with the first power supply 51 and a second temperature controller 149 in electrical communication with the second power supply 151.

If desired, a first surface mount RTD or thermal diode may be electrically connected to the first temperature controller 49 in a feedback control loop adapted to control the first power signal based on the DUT temperature detected by the first RTD or diode. A second surface mount RTD or thermal diode may be electrically connected to the second temperature controller 149 in a feedback control loop adapted to control the second power signal based on the DUT temperature detected by the second RTD or diode. Thus, rather than providing differential power signals based on a predetermined temperature profile of various DUT areas, such as memory 70 and driver 71 areas, the differential power signals may be provided in a feedback loop based on the detected temperature in various DUT areas or regions. In this case, a DUT temperature at a first DUT area 70 and a second DUT area 71 is determined. The first power signal is provided to a plurality of discrete heating elements adjacent to the first DUT area 70 in response to the detected temperature at the first DUT area. The second power signal different than the first power signal is provided to a plurality of discrete heating elements adjacent to the second DUT area 71 in response to the temperature detected at the second DUT area.

Therefore, the hot and cold spots due to DUT 53 architecture and due to the location of the heat exchange fluid inlet 25 may be controlled by placing a first set of resistors 3 that have a first density, resistance value and/or applied power adjacent to the cold spot, while placing the second set of resistors 3 that have a different, second density, resistance value and/or applied power adjacent to the hot spot.

When the system of FIGS. 4 and 5 are in use, a top surface of a DUT 53 is placed in contact with the DUT contact area 7 of the heating apparatus 1. The bottom surface of the DUT 53 containing output pins or vias is placed into a test head, which includes a testing socket 55. The socket 55 is mounted on a substrate 57, such as a printed circuit board. The socket 55 sends and receives DUT electrical testing signals through wires or metal lines 59 from a second power source 61, which is controlled by a computer or a testing control circuit (not shown). The testing signals may be used to test the DUT speed or operating frequency, for example, if the DUT 53 is a microprocessor chip.

In one preferred embodiment of the present invention, the heating apparatus 1 is incorporated into a manually DUT loading testing system 41, such as the ETC-1000 system manufactured by Schlumberger. In this embodiment, the heating apparatus 1 is attached to the container 43 and the control module 47 via a static boom arm 63. In this static system, the wires 45 and the heat exchange fluid inlet and outlet 25, 27 pass through the boom arm 63 to a remote location containing the container 43 and control module 47. The DUT 53 may be placed into the socket 55 manually, and then the heating apparatus 1 may be placed in contact with the DUT 53.

In another preferred embodiment of the present invention, the heating apparatus 1 is incorporated into a dynamic testing system 41, such as the TCH-1000 system manufactured by Schlumberger. In this embodiment, the heating apparatus 1 comprises a portion of a DUT handler 63, which moves the DUT 53 between different preheating, testing and cooling stations. The heating apparatus 1 comprises the end section of a movable portion of the handler 63. The DUT 55 is first attached to the heating apparatus 1 by conventional attachment elements, such as mechanical grippers. The handler 63 then moves the DUT 55 attached to the heating apparatus 1 in and out of the socket 55.

A preferred method of testing the DUT 53 using the system 41 will now be described. First, a DUT 53, such as a packaged semiconductor memory or logic chip is fabricated using conventional semiconductor fabrication and packaging techniques. The DUT 53 is placed in contact with a DUT contact surface or area 7 of the heating apparatus 1. An electrical testing input signal is provided to the DUT 53 from the second power source 61. An electrical testing output signal is received from the DUT 55 and analyzed to determine a DUT characteristic, such as its operating frequency. During testing, the DUT 53 is heated with a plurality of discrete heating elements 3 located in thermal communication with the DUT contact surface 7, while a heat exchange fluid is provided into the heat exchange passage 23 adjacent to the heating elements 3. Preferably, the heat exchange fluid flows directly over an outer surface of the heating elements. The heat exchange fluid may be a halogenated ether fluid, such as a fluid which comprises ethyl nonafluorobutylether and ethyl nonafluoroisobutylether.

An approximate DUT temperature is detected by the RTD(s) 9, which provide an output signal to the temperature controller 49. The temperature controller 49 determines the DUT 53 temperature based on the signal from the RTD(s) 9. In response to the determined DUT temperature, the temperature controller 49 adjusts the power supplied from the power source 51 to the plurality of discrete heating elements 3 by providing a control signal to the power source 51. For example, the power may be adjusted in order to allow the DUT 53 to reach a desired set point temperature. Preferably, the RTD(s) 9 are electrically connected to the temperature controller 49 in a closed feedback control loop, which is adapted to control a power supplied to the resistors 3 based on the DUT temperature detected by the RTD(s) 9. However, if desired, the temperature can be controlled in an open loop set up or in a “power following mode”, where the temperature is controlled based on the testing power input into the DUT, as described in PCT published application PCT/US99/15846 filed on Jul. 14, 1999, which corresponds to U.S. application Ser. No. 09/352,760 filed Jul. 14, 1999, both incorporated herein by reference in their entirety.

A preferred method of making the heating apparatus 1 will now be described. A DUT contact surface or area 7, which is adapted to be in contact with a single DUT, is provided. The contact surface 7 preferably comprises at least a major portion of the AIN pad 5. Preferably, a plurality of metal conductors 11 are formed on the DUT contact surface and a thermally conductive material 15 is formed on the DUT contact surface between the conductors.

A plurality of discrete surface mount resistors 3 are mounted on the DUT contact surface 7 on pad 5. Preferably, the resistors 3 are mounted over the optional thermally conductive material 15, such that the resistor 3 electrodes are in contact with the conductors 11. The resistor electrodes are then soldered to the conductors 11. Furthermore, at least one surface mount RTD 9 is preferably mounted on the DUT contact surface 7. Preferably, the RTD 9 is mounted on a different set of conductors 11 than the resistors 3. Post connector(s) 17 are also mechanically attached or soldered to the conductors 11, as described above.

An enclosure 19 is placed over the resistors 3 to form a heat exchange fluid passage 23 bounded by an outer surface of the resistors 3, an inner surface of the enclosure 19 and an outer surface of the pad 5 and the conductors 11. A heat exchange fluid inlet 25 is connected to the heat exchange fluid passage. Post connectors 17 and wires 45 connect the metal conductors 11 to the power source 51 and the temperature controller 49.

In a preferred aspect of the present invention, it is first determined whether a first DUT area that will reach a higher temperature than a second DUT area during a DUT testing step. Then, based on the determination, a first set of resistors having a first density and/or resistance value are mounted over a first DUT contact surface portion that will be in thermal communication with the first DUT area and a second set of resistors having a higher, second density and/or a different resistance value are mounted in a second DUT contact surface portion that will be in thermal communication with the second DUT area. Furthermore, the first set of resistors may be connected to the first power source 51 that supplies a first power signal, while the second set of resistors may be connected to the second power source 151 that supplies a second power signal that is lower than the first signal. This connection to different power sources may be done instead of or in addition to varying the resistor density and/or resistance between the first and second sets of resistors.

Furthermore, the size of the heating apparatus 1 may be adjusted to match the size of the DUT 53. Thus, a size of the DUT 53 that will be placed in contact with the apparatus 1 is determined. Then, the DUT contact surface 7 is patterned to have a comparable size to that of the DUT 53. The resistor pattern is then selected to fill the contact surface 7, and the resistors 3 are mounted on the contact surface 7. However, in an alternative embodiment, the apparatus 1 may have plural DUT contact surfaces 7 that contact plural DUTs 53. Preferably, a plurality of resistors 3 are mounted over each DUT contact surface 7. In other words, the apparatus 1 may have one large DUT contact surface 7, and a plurality of resistors may be mounted over each portion of such surface 7 that is adapted to be in contact with a single DUT.

The heating apparatus 1 described above has many advantages over the prior art heating devices. First, the apparatus 1 uses high power, highly reliable and commercially available surface mount resistors 3. This is advantageous because the extra complexity, development time and costs associated with custom made thin film resistors can be avoided. Second, the commercially available RTDs 9 are precalibrated to industry standards, thus avoiding the difficulty in calibrating custom made temperature detectors and avoiding the use of a customized temperature correlation database. However it is noted that the sensor may alternatively comprise a thermocouple, thermal diode, a temperature sensor unit with built in signal conditioning or signal processing capabilities. These alternative devices may require a temperature correlation database. Third, the apparatus 1 is flexible in terms of physical size, heater resistance and temperature detector properties by virtue of its design. Fourth, by using a plurality of discrete resistors 3 and/or RTDs 9, a redundancy is built into the heating apparatus 1. In contrast, in the prior art devices, a failure of the thin film resistor or the temperature detector causes the failure of the entire device. Fifth, since the resistors 3 form a boundary of the heat exchange fluid path 23, the poor thermal conductivity and leaks associated with prior art fluid exchange pipes is avoided. Furthermore, by placing a higher density of resistors 3 or resistors with a different resistance value adjacent to the fluid inlet 25, the formation of cold spots is reduced or avoided.

As one of ordinary skill in the relevant art will readily appreciate, in light of the present and incorporated disclosures, the functions of the system 41 can be implemented with a variety of techniques. In accordance with an aspect of the present invention, the functionality disclosed herein can be implemented by hardware, software, and/or a combination of both.

Electrical circuits, using analog components, digital components, or a combination may be employed to implement the control, processing, and interface functions. Software implementations can be written in any suitable language, including without limitation high-level programming languages such as C++, mid-level and low-level languages, assembly languages, application-specific or device-specific languages, and graphical languages such as Lab View. Such software can run on a general purpose computer containing a Pentium processor, an application specific piece of hardware, or other suitable device. In addition to using discrete hardware components in a logic circuit, the required logic may also be performed by an application specific integrated circuit (“ASIC”) or other device.

The system 41 may also include various hardware components which are well known in the art, such as connectors, cables, and the like. Moreover, at least part of the system functionality may be embodied in transmitted waveform or in computer readable media (also referred to as computer program products), such as magnetic, magnetic-optical and optical media.

Furthermore, the heating apparatus 1 can be applied to a variety of different fields, applications, industries, and technologies other than a semiconductor chip speed testing system 41. The apparatus 1 can be used with any system in which temperature must either be monitored or controlled. The temperature of interest may be that of any physical entity, including, without limitation, an electronic device or its environment, such as air molecules either in a flow or stationary.

The principles, preferred embodiments, and modes of operation of the present invention have been described in the foregoing specification. The invention is not to be construed as limited to the particular forms disclosed, because these are regarded as illustrative rather than restrictive. Moreover, variations and changes may be made by those of ordinary skill in the art without departing from the spirit and scope of the invention.

We claim:

1. A heating apparatus, comprising:
at least one DUT contact area adapted to be in contact with a single DUT;
a plurality of discrete heating elements in thermal communication with the DUT contact area; and
a heat exchange fluid passage.

2. The apparatus of claim 1, further comprising a plurality of DUT contact areas, each DUT contact area adapted to be in contact with a single DUT.

3. The apparatus of claim 1, wherein:
the DUT contact area comprises a ceramic pad or a compliant high temperature plastic pad; and
the discrete heating elements comprise surface mount resistors having a first surface over the pad.

4. The apparatus of claim 3, wherein:
the pad comprises a ceramic AlN pad containing metal conductors; and
the surface mount resistors are soldered to the metal conductors.

5. The apparatus of claim 3, wherein a resistance value of the surface mount resistors over a first portion of the DUT contact area is different than a resistance value of the surface mount resistors over a second portion of the DUT contact area.

6. The apparatus of claim 5, wherein the first portion includes a heat exchange fluid inlet or the first portion is adapted to be in contact with a first section of a DUT that generates less heat during testing than a second section of the DUT.

7. The apparatus of claim 1, wherein the discrete heating element density over a first portion of the DUT contact area is greater than the discrete heating element density over a second portion of the DUT contact area.

8. The apparatus of claim 7, wherein the first portion includes a heat exchange fluid inlet or the first portion is adapted to be in contact with a first section of a DUT that generates less heat during testing than a second section of the DUT.

9. The apparatus of claim 3, wherein the heat exchange fluid passage is bounded by a second surface of the surface mount resistors and an inner surface of an enclosure enclosing the surface mount resistors.

10. A heating system, comprising:
the heating apparatus of claim 9; and
a temperature controller in electrical communication with the plurality of discrete heating elements.

11. The system of claim 10, further comprising:
a thermally conductive epoxy between the first surface of the surface mount resistors and the pad;
at least one surface mount RTD mounted over the pad and electrically connected to the temperature controller in a feedback control loop adapted to control a power supplied to the resistors based on the DUT temperature detected by the RTD;
a low voltage power source whose power output is controlled by the controller;
a plurality of low voltage power amplifiers electrically connected to the power source; and
at least one spring loaded pogo post connector or stationary post connector between the metal conductors and the power source, protruding through the enclosure.

12. A heating apparatus, comprising:
a plurality of discrete heating elements;
an enclosure enclosing the heating elements; and
a heat exchange fluid passage bounded by an outer surface of the heating elements and an inner surface of the enclosure.

13. The apparatus of claim 12, wherein:
the discrete heating elements comprise surface mount resistors having a first surface over a pad;
a first portion of the enclosure contacts the pad; and
the heat exchange fluid passage comprises a first area between sidewalls of the resistors, the inner surface of the enclosure and an inner surface of the pad.

14. The apparatus of claim 13, further comprising:
a thermally conductive material between a first surface of the resistors and the pad; and
a thermally insulating material between a second surface of the resistors and the enclosure.

15. A heating system comprising:
the apparatus of claim 13;
a heat exchange fluid container;
a heat exchange fluid inlet passing through the enclosure and connecting the heat exchange fluid container with the heat exchange fluid passage; and
a temperature controller in electrical communication with the plurality of discrete heating elements.

16. The system of claim 15, wherein:
the pad comprises a ceramic AlN pad or a compliant high temperature plastic pad containing metal conductors, the pad containing at least one DUT contact area which is adapted to be in contact with a single DUT;
the surface mount resistors are soldered to the metal conductors; and
a density of the resistors in a first area adjacent to the heat exchange fluid inlet is higher than that in a second area distal from the heat exchange fluid inlet or a resistance value of the resistors in the first area adjacent to the heat exchange fluid inlet is different than that in the second area distal from the heat exchange fluid inlet.

17. A heating apparatus, comprising:
at least one DUT contact area adapted to be in contact with a single DUT;
a plurality of discrete heating elements in thermal communication with the DUT contact area;
an enclosure enclosing the heating elements; and
a heat exchange fluid passage bounded by an outer surface of the heating elements and an inner surface of the enclosure.

18. The apparatus of claim 17, wherein:
the at least one DUT contact area comprises a ceramic or compliant high temperature plastic pad containing metal conductors;
the discrete heating elements comprise surface mount resistors soldered to the metal conductors;
a first portion of the enclosure contacts the pad; and
the heat exchange fluid passage comprises a first area between sidewalls of the resistors, the inner surface of the enclosure and an inner surface of the pad.

19. A heating system, comprising:
the apparatus of claim 18;
a temperature controller in electrical communication with the plurality of discrete heating elements;
a thermally conductive epoxy between a first surface of the surface mount resistors and the pad comprising a ceramic AlN pad;
a thermally insulating epoxy between a second surface of the resistors and the enclosure;
at least one surface mount RTD mounted over the AIN pad and electrically connected to the temperature controller in a feedback control loop adapted to control a power supplied to the resistors based on the DUT temperature detected by the RTD;
a low voltage power source whose power output is controlled by the controller;
a plurality of low voltage power amplifiers electrically connected to the power source;
at least one post connector between the metal conductors and the power source, protruding through the enclosure;
a heat exchange fluid container; and
a heat exchange fluid inlet passing through the enclosure and connecting the heat exchange fluid container with the heat exchange fluid passage.

20. The system of claim 19, wherein the resistor density over a first portion of the DUT contact area is greater than that over a second portion of the DUT contact area or a resistance value of the resistors over a first portion of the DUT contact area is different than that over a second portion of the DUT contact area.

21. The system of claim 20, wherein the first portion includes a heat exchange fluid inlet or the first portion is adapted to be in contact with a first section of a DUT that generates less heat during testing than a second section of the DUT.

22. A DUT testing system, comprising:
the heating apparatus of claim 17;
a test head containing a DUT testing socket adapted to be positioned opposite the heating apparatus; and
a second power source adapted to provide a DUT electrical testing signal to the socket.

23. The system of claim 22, further comprising a DUT handler adapted to move the DUT in and out of the socket while the DUT is in contact with the DUT contact area.

24. A heating apparatus, comprising:
at least one DUT contact area adapted to be in contact with a single DUT;
a first set of discrete heating elements in thermal communication with a first portion of the DUT contact area;
a second set of discrete heating elements in thermal communication with a second portion of the DUT contact area adapted to heat the second portion of the DUT contact area to a lower temperature than the first portion of the DUT contact area; and
a heat exchange fluid passage.

25. The apparatus of claim 24, wherein:
the heating elements comprise surface mount resistors; and
the average resistance value of the surface mount resistors over the first portion of the DUT contact area is different than the average resistance value of the surface mount resistors over the second portion of the DUT contact area.

26. The apparatus of claim 25, wherein the first portion includes a heat exchange fluid inlet.

27. The apparatus of claim 25, wherein the first portion is adapted to be in contact with a first area of a DUT that generates less heat during testing than a second area of the DUT.

28. The apparatus of claim 24, wherein the discrete heating element density over a first portion of the DUT contact area is greater than the discrete heating element density over a second portion of the DUT contact area.

29. The apparatus of claim 28, wherein the first portion includes a heat exchange fluid inlet.

30. The apparatus of claim 28, wherein the first portion is adapted to be in contact with a first area of a DUT that generates less heat during testing than a second area of the DUT.

31. The apparatus of claim 24, wherein:
the DUT contact area comprises a ceramic pad or a compliant high temperature plastic pad containing metal conductors;
the discrete heating elements comprise surface mount resistors having a first surface over the pad;
the surface mount resistors are soldered to metal conductors; and
the heat exchange fluid passage is bounded by a second surface of the surface mount resistors and an inner surface of an enclosure enclosing the surface mount resistors.

32. A heating system comprising:
the heating apparatus of claim 24;
a first power supply in electrical communication with the first set of a plurality of discrete heating elements and which is adapted to provide a first power signal to the first set of discrete heating elements;
a second power supply in electrical communication with the second set of a plurality of discrete heating elements and which is adapted to provide a second power signal to the second set of discrete heating elements which is lower than the first power signal; and
at least one temperature controller in electrical communication with the first and second power supplies.

33. The system of claim 32, further comprising:
a first temperature controller in electrical communication with the first power supply;
a second temperature controller in electrical communication with the second power supply;
a first surface mount RTD or thermal diode electrically connected to the first temperature controller in a feedback control loop adapted to control the first power signal based on the DUT temperature detected by the first RTD or thermal diode;
a second surface mount RTD or thermal diode electrically connected to the second temperature controller in a feedback control loop adapted to control the second power signal based on the DUT temperature detected by the second RTD or thermal diode.

34. A method of making a heating apparatus, comprising:
providing a DUT contact surface;
mounting a plurality of discrete surface mount resistors on a portion of the DUT contact surface adapted to be in contact with a single DUT; and
placing an enclosure over the resistors to form a heat exchange fluid passage bounded by an outer surface of the resistors and an inner surface of the enclosure.

35. The method of claim 34, wherein the step of mounting comprises:
forming a plurality of metal conductors on the DUT contact surface;
forming a thermally conductive material on the DUT contact surface between the conductors;
placing the resistors on the DUT contact surface such that the resistor electrodes are in contact with the conductors; and
soldering the resistor electrodes to the conductors.

36. The method of claim 35, further comprising:
mounting at least one surface mount RTD on the DUT contact surface;
connecting a heat exchange fluid inlet to the heat exchange fluid passage; and
connecting at least one power source to the metal conductors using a post connector.

37. The method of claim 34, further comprising:
determining a first DUT area that will reach a higher temperature than a second DUT area during a DUT testing step; and
mounting a lower density of resistors over a first DUT contact surface portion that will be in thermal communication with the first DUT area than in a second DUT contact surface portion that will be in thermal communication with the second DUT area.

38. The method of claim 34, further comprising:
determining a first DUT area that will reach a higher temperature than a second DUT area during a DUT testing step;
mounting a first set of resistors having a first average resistance value over a first DUT contact surface portion that will be in thermal communication with the first DUT area; and
mounting a second set of resistors having a second average resistance value different than the first resistance value over a second DUT contact surface portion that will be in thermal communication with the second DUT area.

39. The method of claim 34, further comprising:
determining a size of the DUT; and
patterning the DUT contact surface to have a comparable size to that the DUT.

40. A method of testing a DUT, comprising:
placing the DUT in contact with a DUT contact surface;
providing an electrical testing input signal to the DUT;
receiving an electrical testing output signal from the DUT;
heating the DUT witha plurality of discrete heating elements located in thermal communication with the DUT contact surface; and
providing a heat exchange fluid into a heat exchange passage adjacent to the plurality of discrete heating elements.

41. The method of claim 40, further comprising:
determining the DUT temperature; and
adjusting a power supplied to the plurality of discrete heating elements in response to the determined DUT temperature.

42. The method of claim 41, further comprising:
providing a first power signal to a plurality of discrete heating elements adjacent to a first DUT region; and
providing a second power signal different than the first power signal to a plurality of discrete heating elements adjacent to a second DUT region.

43. The method of claim 41, further comprising:
determining a DUT temperature at the first DUT region and the second DUT region;
providing a first power signal to the plurality of discrete heating elements adjacent to the first DUT region in response to the determined temperature at the first DUT region; and
providing a second power signal different than the first power signal to plurality of discrete heating elements adjacent to the second DUT region in response to the determined temperature at the second DUT region.

44. The method of claim 41, wherein:
determining the DUT temperature comprises detecting an approximate DUT temperature using an RTD or thermal diode and providing the RTD or thermal diode output to a temperature controller; and
adjusting the power comprises providing a control signal from a temperature controller to a low voltage power source and providing a low voltage power to the heating elements.

45. The method of claim 40, wherein the step of providing the heat exchange fluid through the heat exchange passage comprises flowing a halogenated ether fluid directly over an outer surface of the heating elements.

46. The method of claim 45, wherein the halogenated ether fluid comprises ethyl nonafluorobutylether and ethyl nonafluoroisobutylether.

47. The method of claim 40, wherein the discrete heating elements comprise surface mount resistors.

48. The method of claim 47, further comprising heating a first portion of a DUT to a higher temperature than a second portion of a DUT.

49. The method of claim 48, wherein a density of the surface mount resistors is greater adjacent to the first portion of a DUT than to the second portion of a DUT or an average resistance value of the surface mount resistors adjacent to the first portion of a DUT is different than to the second portion of a DUT.

50. The method of claim 40, further comprising fabricating the DUT comprising a semiconductor chip prior to the step of placing the DUT.

51. A semiconductor chip made by the process of claim 50.
